(19) United States
(12) Patent Application Publication
(10) Pub. No.: US 2014/0054156 A1
(43) Pub. Date: Feb. 27, 2014

(54) TOUCH-SENSING ELECTRODE STRUCTURE AND TOUCH-SENSITIVE DEVICE

(71) Applicant: WINTEK CORPORATION, Taichung City (TW)

(72) Inventors: Ting-Yu CHANG, Feng Shan City (TW); Hsiao-Hui LIAO, Taichung City (TW); Kun-Chang HO, Tai Chung City (TW); Fa-Chen WU, Tai Chung City (TW); Kuang-Wei LI, Tai Ping City (TW); Kuo-Chang SU, Shan Hua Town (TW)

(73) Assignee: Wintek Corporation, Taichung City (TW)

(21) Appl. No.: 13/970,142

(22) Filed: Aug. 19, 2013

(30) Foreign Application Priority Data
Aug. 21, 2012 (TW) 101130198

(51) Int. Cl. H03K 17/96

(52) U.S. Cl. CPC H03K 17/9622
USPC 200/600

(57) ABSTRACT

A touch-sensing electrode structure includes multiple first electrodes and multiple second electrodes. Each first electrode includes a longitudinal part extending in a first direction and multiple branch parts connected to the longitudinal part. The second electrodes are disposed on at least one side of each longitudinal part, and each of the second electrodes at least spreads over a region between two adjacent branch parts of each of the first electrodes.

### BACKGROUND OF THE INVENTION

a. Field of the Invention

The invention relates to a touch-sensing electrode structure and a touch-sensitive device.

b. Description of the Related Art

Nowadays, a touch-sensing electrode structure of a capacitive touch-sensitive device is often fabricated using double-sided ITO or single-sided ITO fabrication processes. On forming conventional double-sided ITO patterns, coating, etching, and photolithography processes are performed on each of a top side and a bottom side of a glass substrate to form X-axis and Y-axis sensing electrodes on the two sides. However, except for being complicated, such fabrication processes may cause low production yields because of the step of flipping over the glass substrate to achieve double-sided patterning. In comparison, on forming conventional single-sided ITO patterns, since X-axis and Y-axis sensing electrodes are formed on the same side of a glass substrate, a bridge wiring structure needs to be formed in a touch screen area. In that case, unstable material characteristics of an organic insulation layer or other factors may cause short-circuit or open-circuit of the X-axis and Y-axis sensing electrodes. Therefore, a single-layer electrode structure is proposed to resolve above problems, where X-axis and Y-axis sensing electrodes are formed in the same layer to simplify fabrication process, increase production yields and reduce fabrication costs. However, in a single-layer electrode structure, an improved electrode layout is needed to achieve better characteristics of touch-sensing controls, such as sufficient coupling-capacitance variations and fine linearity of electric fields. Further, the amount of channels needed for a single-layer electrode structure is very large, and this may result in excessively large bonding areas formed by X-axis and Y-axis sensing electrodes on a flexible printed circuit board and cause high line impedance.

### BRIEF SUMMARY OF THE INVENTION

The invention provides a touch-sensing electrode structure and a touch-sensitive device having low line impedance and improved sensitivity and linearity for touch-sensing controls.

According to one embodiment of the invention, a touch-sensing electrode structure includes multiple first electrodes and multiple second electrodes. Each first electrode includes a longitudinal part extending in a first direction and multiple branch parts connected to the longitudinal part. The second electrodes are disposed on at least one side of each longitudinal part, and each of the second electrodes at least spreads over a region between two adjacent branch parts of each of the first electrodes.

In one embodiment, the branch parts of one of the first electrodes have different widths measured in a second direction different to the first direction. The widths of the branch parts of the first electrode may decrease progressively in a direction away from the longitudinal part of the first electrode.

In one embodiment, the branch parts of one of the first electrodes make different angles with the longitudinal part of the first electrode.

In one embodiment, at least two of the second electrodes are disposed symmetrically on two sides of the longitudinal part. Each of the second electrodes includes a plurality of branch parts, and the branch parts of the second electrode are adjacent to the longitudinal part or the branch parts of the first electrode. The branch parts of one of the second electrodes have different widths measured in a second direction different to the first direction. The widths of the branch parts of the second electrode may decrease progressively in a direction away from the longitudinal part of the first electrode.

In one embodiment, each of the first electrodes is a signal-transmitting electrode, and each of the second electrodes is a signal-sensing electrode.

In one embodiment, each of the branch parts of the first electrode is in the form of a first block, each of the second electrodes is in the form of a second block, the touch-sensing electrode structure has multiple first blocks and multiple second blocks, and the first blocks and the second blocks are alternately arranged on each of two opposed sides of the longitudinal part. The first blocks and the second blocks may form a delta topological electrode layout.

In one embodiment, each of the first blocks is partitioned by the second electrode to form a plurality of first regions, and the first regions of the same first block have mutually different widths measured in a second direction substantially perpendicular to the first direction.

In one embodiment, each of the second blocks is partitioned by the first electrode to form a plurality of second regions, and the second regions of the same second block have mutually different widths measured in a second direction substantially perpendicular to the first direction.

According to another embodiment of the invention, a touch-sensitive device includes a substrate, a touch-sensing electrode structure, a plurality of conductive wires, and a flexible printed circuit board. The touch-sensing electrode structure is disposed on the substrate and has a plurality of first electrodes and second electrodes. The touch-sensing electrode structure is partitioned to form a plurality of blocks adjacent to each other, and each of the blocks has at least one first electrode and a plurality of second electrodes. Each of the conductive wires is connected to one of the first electrodes or one of the second electrodes. The flexible printed circuit board is electrically connected to the touch-sensing electrode structure. The first electrode and the plurality of second electrodes in the same block are connected to the flexible printed circuit board through the conductive wires to form a bonding area on the flexible printed circuit board, the flexible printed circuit board is provided with a plurality of bonding areas, and two adjacent bonding areas on the flexible printed circuit board are situated at different distances from the substrate.

In one embodiment, the touch-sensitive device further includes a plurality of grounding wires, and each of the grounding wires is disposed on a boundary between the two adjacent bonding areas.

In one embodiment, a plurality of bonding pads are disposed in each of the bonding areas.

In one embodiment, a plurality of bus lines are disposed on the flexible printed circuit board. The second electrodes are divided into multiple electrode groups, each electrode group is formed by the second electrodes collected from each of the blocks, and the conductive wires connected to the second electrodes in the same electrode group are all connected to the same bus line. The bus lines may be made of metal.

In one embodiment, a decorative layer is disposed on a periphery of the substrate, and the decorative layer may include at least one of ceramic, diamond-like carbon, colored ink, photo resist and resin.

In one embodiment, a passivation layer is disposed on the substrate and covering the touch-sensing electrode structure. The passivation layer may be a refractive-index matching layer.

According to another embodiments of the invention, a touch-sensing electrode structure includes a plurality of first electrodes and a plurality of second electrodes. Each of the electrodes has a major part extending in a first direction and a plurality of branch parts connected to the major part. The second electrodes are disposed on at least one side of each major part, and each of the second electrodes at least spreads over a region between two adjacent branch parts of each of the first electrodes. The branch parts of one of the first electrodes have different widths measured in a second direction different to the first direction.

According to the above embodiments, since multiple sides of the second electrode are adjacent to a longitudinal part or branch parts of the first electrode, the intensity of an electric field formed between the first electrode and the second electrode is increased to increase the amount of coupling capacitance and the sensitivity of touch-sensing controls for a touch-sensing electrode structure. Further, different regions of the first electrode or the second electrode may have mutually different widths to increase the linearity of touch-sensing controls. Besides, two adjacent bonding areas on a flexible printed circuit board may be situated at different distances from a substrate to decrease an entire occupied space of the bonding areas, and the conductive wires connected to the same electrode group are all connected to the same bus line to reduce the amount of channels and line impedance for a single-layer touch-sensing structure.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 shows a schematic diagram of a touch-sensitive device according to an embodiment of the invention.

FIG. 2 shows a schematic plan view of a touch-sensing electrode structure according to an embodiment of the invention.

FIG. 3 shows a schematic plan view of a touch-sensing electrode structure according to another embodiment of the invention.

FIG. 4 shows a schematic plan view of a touch-sensing electrode structure according to another embodiment of the invention.

FIG. 5 shows a schematic plan view of a touch-sensing electrode structure according to another embodiment of the invention.

FIG. 6 shows a schematic plan view of a touch-sensing electrode structure according to another embodiment of the invention.

FIG. 7 shows a schematic plan view of a touch-sensing electrode structure according to another embodiment of the invention.

FIG. 8 shows a schematic diagram of a touch-sensitive device according to another embodiment of the invention.

FIG. 9 shows a schematic diagram of a touch-sensitive device according to another embodiment of the invention.

### DETAILED DESCRIPTION OF THE INVENTION

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

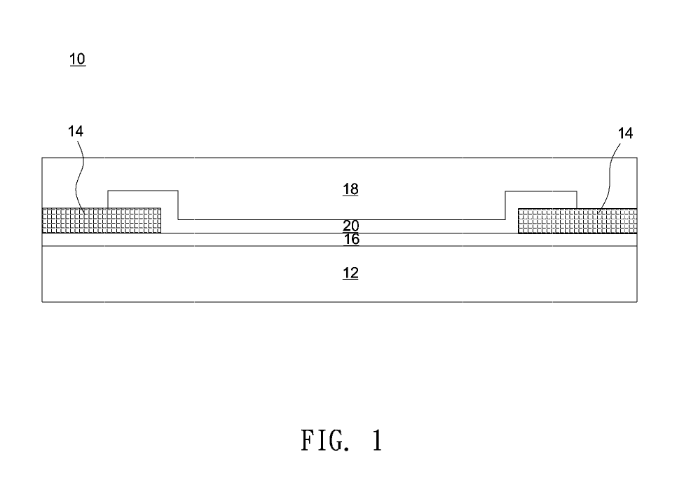

FIG. 1 shows a schematic diagram of a touch-sensitive device according to an embodiment of the invention. As shown in FIG. 1, in a touch-sensitive device 10, a touch-sensing electrode structure 20 is disposed on a substrate 12. The substrate 12 may be a substrate of a display. For example, the substrate 12 may be an encapsulation substrate of an OLED, a color filter substrate or an array substrate. Alternatively, the substrate 12 may be a cover lens. Further, the touch-sensing electrode structure 20 may be disposed on a front side of the substrate 12 facing a user or a back side of the substrate 12 opposite the front side, according to actual demands In one embodiment, a decorative layer 14 is disposed on a periphery of the substrate 12. The decorative layer 14 may include at least one of ceramic, diamond-like carbon, colored ink, photo resist and resin. The substrate 12 may be a glass substrate or a plastic substrate. An insulation layer 16 may be disposed between the touch-sensing electrode structure 20 and the substrate 12. A passivation layer 18 may be disposed on the substrate 12 and covers the touch-sensing electrode structure 20 and the decorative layer 14. In one embodiment, except for protecting touch-sensing electrodes, the passivation layer may also function as a refractive-index matching layer to eliminate retained shadows of the touch-sensing electrodes. The passivation layer may be in the form of a single-layer structure or a multi-layer structure.

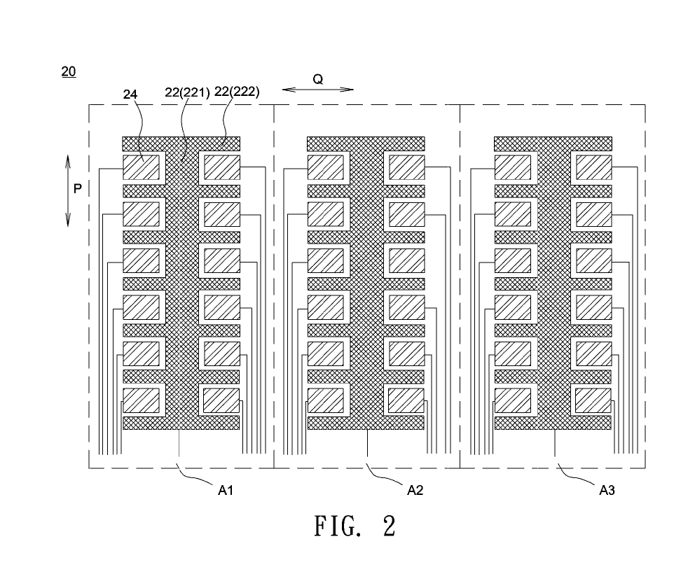

According to an embodiment of the invention, the touch-sensing electrode structure 20 is a single-layer electrode structure. FIG. 2 shows a schematic plan view of a touch-sensing electrode structure according to an embodiment of the invention. Referring to FIG. 2, the touch-sensing electrode structure 20 includes multiple first electrodes 22 and multiple second electrodes 24. Each first electrode 22 includes a longitudinal pan 221 extending in a direction P and multiple branch parts 222 connected to the longitudinal part 221. The second electrodes 24 are disposed separate from each other. Note the term “longitudinal part” as used in the specification and the appended claims refers to a part of an electrode having a longer length in one direction compared with the lengths measured in other directions, but is not used to define or limit the shape of an electrode. In this embodiment, at least two of the second electrodes 24 are disposed symmetrically on two sides of the longitudinal part 221. The branch parts 222 extend in a direction Q different to the direction P, and each second electrode 24 at least spreads over a region between two adjacent branch parts 222 of the first electrode 22. In one embodiment, the direction Q may, but not limited to, be substantially perpendicular to the direction P. According to this embodiment, since three sides of the second electrode 24 are adjacent to the longitudinal part 221 and the branch parts 222, the second electrode 24 is substantially surrounded by the first electrode 22. Therefore, the intensity of an electric field formed between the first electrode 22 and the second electrode 24 is increased to increase the amount of coupling capacitance and the sensitivity of touch-sensing controls for the touch-sensing electrode structure 20.

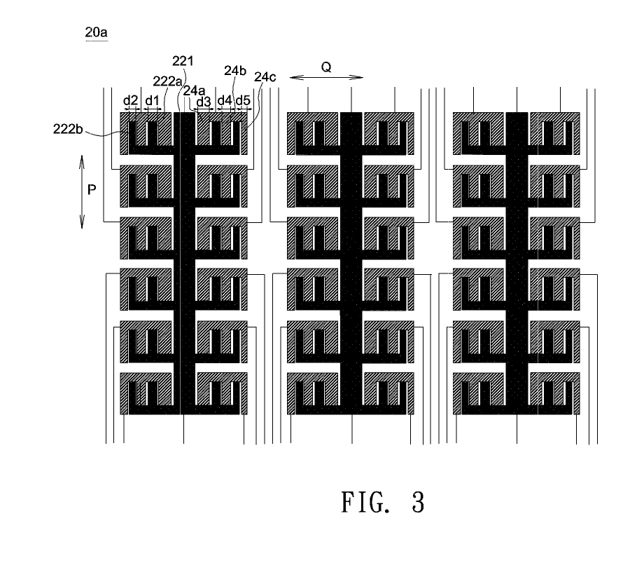

FIG. 3 shows a schematic plan view of a touch-sensing electrode structure according to another embodiment of the invention. As shown in FIG. 3, in a touch-sensing electrode structure 20a, each first electrode 22 includes a longitudinal part 221 extending in the direction P and multiple branch parts 222a and 222b connected to the longitudinal part 221. The branch parts 222a and 222b are disposed on two sides of the longitudinal part 221. In this embodiment, the branch part 222a has a width d1 measured in the direction Q substantially perpendicular to the direction P. the branch part 222b has a width d2 measured in the direction Q, and the width d1 of the branch part 222a is not equal to the width d2 of the branch part 222b. In one embodiment, widths of the branch parts 222a and 222b disposed on the same side of the longitudinal part 221 may progressively decrease in a direction, for example, away from the longitudinal part 221. That is, in one embodiment, the width d2 of the branch part 222b is smaller than the width d 1 of the branch part 222a (d2<d1). In that case, since the width dl of the branch part 222a is set to not equal the width d2 of the branch part 222b, the widths of the branch parts 222a and 222b may be adjusted to increase the sensitivity and linearity of touch-sensing controls. Further, in this embodiment, each second electrode 24 may have multiple branch parts 24a, 24b and 24c, and the branch parts 24a, 24b and 24c are all adjacent to the longitudinal part 221 or branch parts 222 to further increase the amount of coupling capacitance of the touch-sensing electrode structure 20a. Besides, the branch parts 24a, 24b, and 24c may respectively have widths d3, d4 and d5 measured in the direction Q, and the widths d3, d4 and d5 may, but not limited to, decrease progressively in a direction away from the longitudinal part 221 of the first electrode 22 (d5<d4<d3). Under the circumstance, since the widths of the branch parts 24a, 24b and 24c at different positions are mutually different to cause different electrical field intensities, the widths of branch parts at different positions can be adjusted to equalize the capacitance variation at different positions and hence further enhance the sensitivity of touch-sensing controls and the linearity of an induced electrical field.

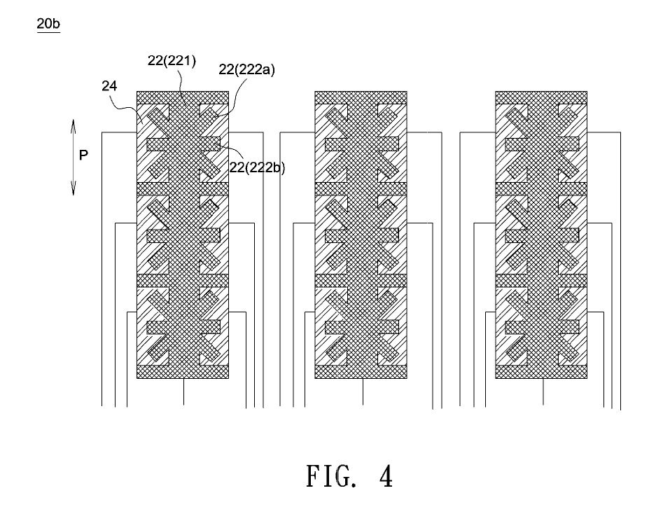

According to the above embodiments of the invention, included angles formed between the branch parts 222 and the longitudinal part 221 of the first electrode 22 are not limited and may include different values. For example, as shown in FIG. 4, in a touch-sensing electrode structure 20b, each first electrode 22 includes a longitudinal part 221 extending in the direction P and multiple branch parts 222a and 222b connected to the longitudinal part 221, where an included angle formed between the branch part 222a and the longitudinal part 221 is different to an included angle formed between the branch part 222b and the longitudinal part 221.

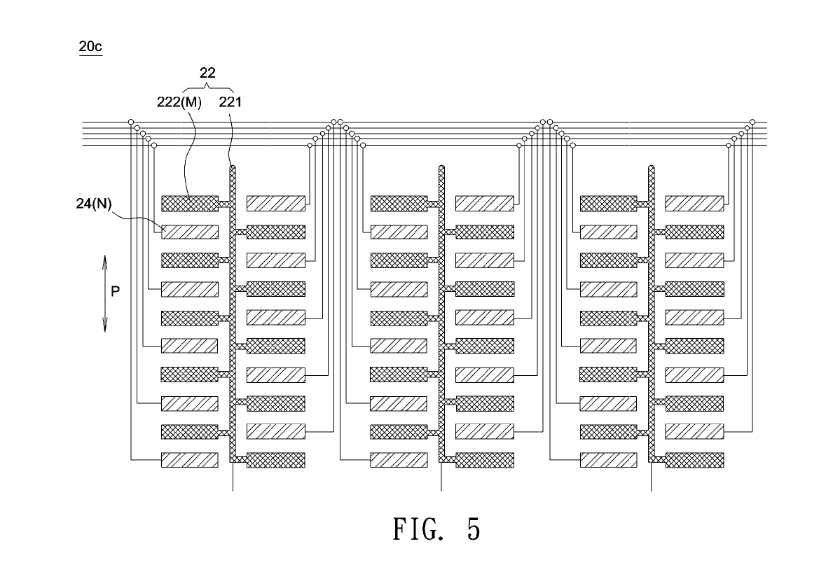

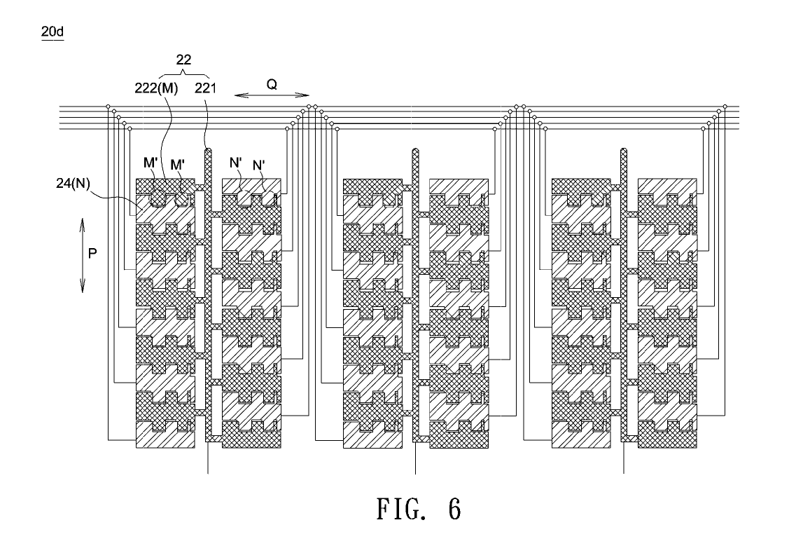

FIG. 5 shows a schematic plan view of a touch-sensing electrode structure according to another embodiment of the invention. As shown in FIG. 5, in a touch-sensing electrode structure 20c, each first electrode 22 includes a longitudinal part 221 extending in the direction P and multiple branch parts 222 connected to the longitudinal part 221. In this embodiment, each branch part 222 is in the form of a block M, and each of the second electrodes 24 that are separate from each other is also in the form of a block N. The multiple blocks M of the first electrode 22 and the multiple blocks N of the second electrode 24 are alternately arranged on each of two opposed sides of the longitudinal part to form a delta topology electrode layout. According to this embodiment, since each block M is surrounded by three blocks N, the intensity of an electric field formed between the first electrode 22 and the second electrode 24 is similarly increased to increase the amount of coupling capacitance and the sensitivity of touch-sensing controls for the touch-sensing electrode structure 20c. As shown in FIG. 6, in an alternate embodiment, the second electrode 24 of the touch-sensing electrode structure 20d partitions each block M to form multiple first regions NC, and the first electrode 22 partitions each block N to form multiple second regions N′. The first regions M′ are interlaced with the second regions N′ to increase the amount of coupling capacitance. In one embodiment, the first regions M′ of the same block M may have mutually different widths measured in the direction Q, and the second regions N′ of the same block N may have mutually different widths measured in the direction Q to increase the linearity of touch-sensing controls.

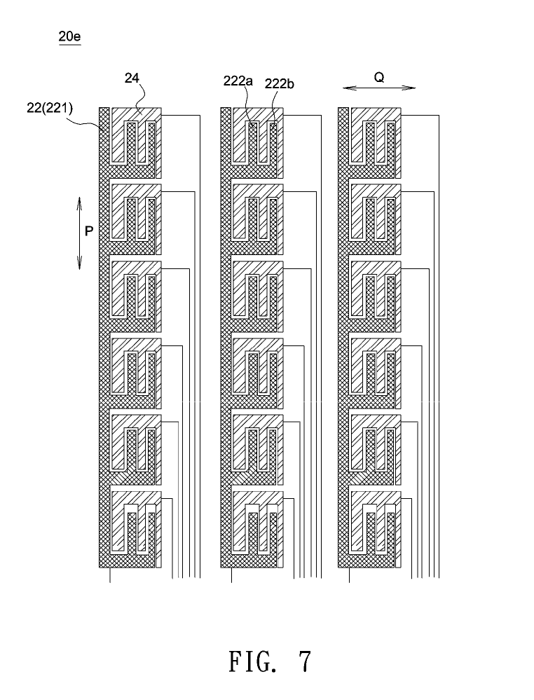

As shown in FIG. 7, in an alternate embodiment, each first electrode 22 of a touch-sensing electrode structure 20e includes a longitudinal part 221 extending in the direction P and multiple branch parts 222 connected to the longitudinal part 221. The second electrodes 24 are disposed on the same side (such as the right-hand side) of each longitudinal part 221. In addition, the branch parts 222a and 222b may have different widths. For example, the widths of the branch parts 222a and 222b may progressively decrease in a direction, such as away from the longitudinal part 221. Besides, in the above embodiments, each first electrode 22 having a longitudinal part 221 that extends in a specific direction may be, for example, a signal-transmitting electrode, and the second electrode 24 may be, for example, a signal-sensing electrode.

It should be noted that the relative positions of aforementioned longitudinal parts and branch parts exemplified in the drawings are not to be construed as limiting the scope of the invention. Any electrode pattern that can be identified to have a major part and at least one branch part subordinate to the major part is within the scope of the present invention.

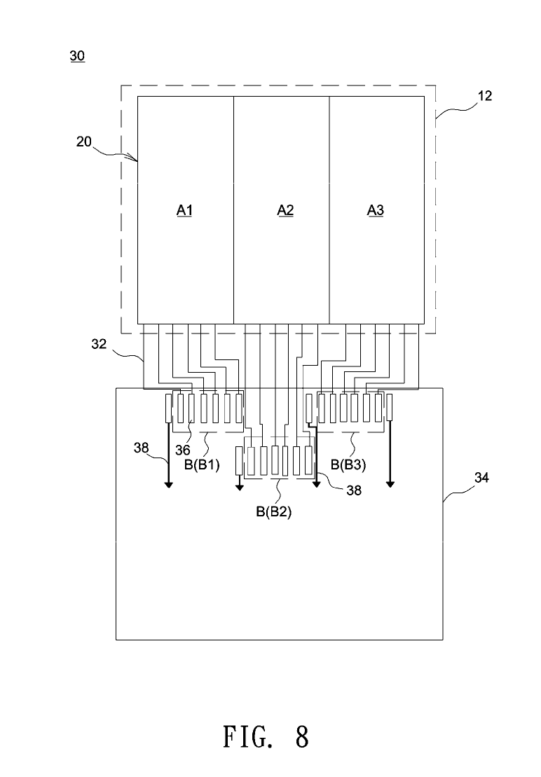

FIG. 8 shows a schematic diagram of a touch-sensitive device according to an embodiment of the invention. As shown in FIG. 8, for example, the touch-sensing electrode structure 20 of a touch-sensitive device 30 is formed on a substrate 12 and partitioned into blocks A1, A2 and A3 adjacent to each other. Each of the blocks A1, A2 and A3 may, for example, include at least one first electrode 22 and multiple second electrodes 24 as shown in FIG. 2. Please refer to both FIG. 2 and FIG. 8, multiple conductive wires 32 are electrically connected to the touch-sensing electrode structure 20 and a flexible printed circuit board 34. Each of the conductive wires 32 is connected to a first electrode 22 or a second electrode 24. The flexible printed circuit board 34 is electrically connected to the touch-sensing electrode structure 20 through the conductive wires 32. In one embodiment, at least one first electrode 22 and multiple second electrodes 24 in the same block are connected to the flexible printed circuit board 34 through the conductive wires 32 to form a bonding area B on the flexible printed circuit board 34. Therefore, the blocks A1, A2 and A3 correspondingly form three bonding areas B1, B2 and B3 through the conductive wires 32 on the flexible printed circuit board 34, and multiple bonding pads 36 are disposed in each of the bonding areas B1, B2 and B3. In this embodiment, since the position of the bonding region B2 on the flexible printed circuit board 34 is shifted downwards, the bonding areas B1 and B2 are allowed to be disposed closer to reduce an entire span of all the bonding areas B1, B2 and B3. That is, two adjacent bonding areas on the flexible printed circuit board 34 are situated at different distances from the substrate 12 to reduce an entire occupied space of all the bonding areas. Further, multiple grounding wire 38 may be disposed on the flexible printed circuit board 34, and each grounding wire 38 may be disposed on a boundary between two adjacent bonding areas B to decrease signal interference.

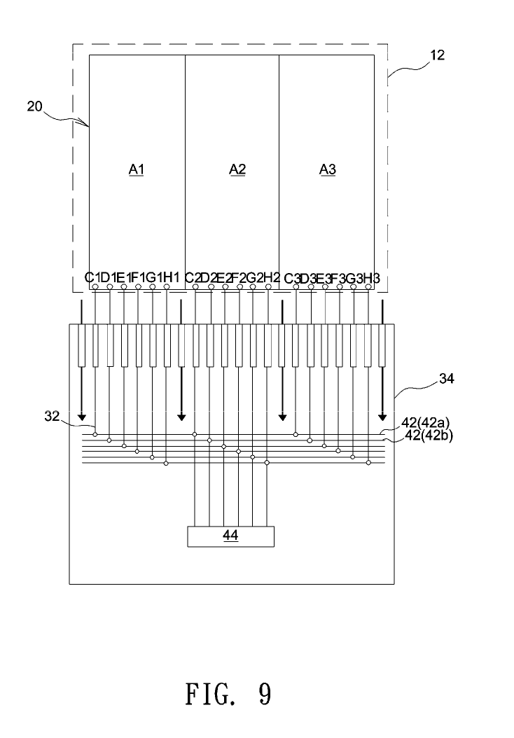

In an alternate embodiment, multiple second electrodes 24 may be divided into multiple electrode groups, and each electrode group is formed by the second electrodes collected from each of the blocks A1-A3. For example, as shown in FIG. 9, the block Al includes second electrodes C1-H1, the block A2 includes second electrodes C2-H2, and the block A3 includes second electrodes C3-H3. A first electrode group includes second electrodes C1, C2, and C3, a second electrode group includes second electrodes D1, D2, and D3, and the rest may be deduced by analogy. In this embodiment, the conductive wires 32 connected to the second electrodes 24 in the same electrode group are all connected to the same bus line 42. For example, the conductive wires in the first electrode group (including second electrodes C1, C2, and C3) are connected to a bus line 42a, the conductive wires in the second electrode group (including second electrodes D1, D2 and D3) are connected to a bus line 42b, and the rest may be deduced by analogy. Each bus line 42 is connected to an IC 44 on the flexible printed circuit board 34. According to this embodiment, the problems of a large amount of channels needed and high line impedance for a single-layer electrode structure can be solved. The bus lines 42 may, but not limited to, be made of metal.

According to the above embodiments, since multiple sides of the second electrode are adjacent to a longitudinal part or branch parts of the first electrode, the intensity of an electric field formed between the first electrode and the second electrode is increased to increase the amount of coupling capacitance and the sensitivity of touch-sensing controls for a touch-sensing electrode structure. Further, different regions of the first electrode or the second electrode may have mutually different widths to increase the linearity of touch-sensing controls. Besides, two adjacent bonding areas on a flexible printed circuit board may be situated at different distances from a substrate to decrease an entire occupied space of the bonding areas, and the conductive wires connected to the same electrode group are all connected to the same bus line to reduce the amount of channels and line impedance for a single-layer touch-sensing structure.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the invention as defined by the following claims. Moreover, no element and component in the present disclosure is intended to be dedicated to the public regardless of whether the element or component is explicitly recited in the following claims. Each of the terms “first” and “second” is only a nomenclature used to modify its corresponding element. These terms are not used to set up the upper limit or lower limit of the number of elements.

What is claimed is:

1. A touch-sensing electrode structure, comprising:
a plurality of first electrodes, each of the first electrodes having a longitudinal part extending in a first direction and a plurality of branch parts connected to the longitudinal part; and
a plurality of second electrodes disposed on at least one side of each longitudinal part, wherein each of the second electrodes at least spreads over a region between two adjacent branch parts of each of the first electrodes.

2. The touch-sensing electrode structure as claimed in claim 1, wherein the branch parts of one of the first electrodes have different widths measured in a second direction different to the first direction.

3. The touch-sensing electrode structure as claimed in claim 2, wherein the widths of the branch parts of the first electrode decrease progressively in a direction away from the longitudinal part of the first electrode.

4. The touch-sensing electrode structure as claimed in claim 1, wherein the branch parts of one of the first electrodes make different angles with the longitudinal part of the first electrode.

5. The touch-sensing electrode structure as claimed in claim 1, wherein at least two of the second electrodes are disposed symmetrically on two sides of the longitudinal part.

6. The touch-sensing electrode structure as claimed in claim 5, wherein each of the second electrodes comprises a plurality of branch parts, and the branch parts of the second electrode are adjacent to the longitudinal part or the branch parts of the first electrode.

7. The touch-sensing electrode structure as claimed in claim 6, wherein the branch parts of one of the second electrodes have different widths measured in a second direction different to the first direction.

8. The touch-sensing electrode structure as claimed in claim 7, wherein the widths of the branch parts of the second electrode decrease progressively in a direction away from the longitudinal part of the first electrode.

9. The touch-sensing electrode structure as claimed in claim 1, wherein each of the first electrodes is a signal-transmitting electrode and each of the second electrodes is a signal-sensing electrode.

10. The touch-sensing electrode structure as claimed in claim 1, wherein each of the branch parts of the first electrode is in the form of a first block, each of the second electrodes is in the form of a second block, the touch-sensing electrode structure has multiple first blocks and multiple second blocks, and the first blocks and the second blocks are alternately arranged on each of two opposed sides of the longitudinal part.

11. The touch-sensing electrode structure as claimed in claim 10, wherein the first blocks and the second blocks form a delta topological electrode layout.

12. The touch-sensing electrode structure as claimed in claim 10, wherein each of the first blocks is partitioned by the second electrode to form a plurality of first regions, and the first regions of the same first block have mutually different widths measured in a second direction substantially perpendicular to the first direction.

13. The touch-sensing electrode structure as claimed in claim 10, wherein each of the second blocks is partitioned by the first electrode to form a plurality of second regions, and the second regions of the same second block have mutually different widths measured in a second direction substantially perpendicular to the first direction.

14. A touch-sensitive device, comprising:
a substrate;
a touch-sensing electrode structure disposed on the substrate and having a plurality of first electrodes and second electrodes, wherein the touch-sensing electrode structure is partitioned to form a plurality of blocks adjacent to each other, and each of the blocks has at least one first electrode and a plurality of second electrodes;
a plurality of conductive wires, wherein each of the conductive wires is connected to one of the first electrodes or one of the second electrodes; and
a flexible printed circuit board electrically connected to the touch-sensing electrode structure, wherein the at least one first electrode and the plurality of second electrodes in the same block are connected to the flexible printed circuit board through the conductive wires to form a bonding area on the flexible printed circuit board, the flexible printed circuit board is provided with a plurality of bonding areas, and two adjacent bonding areas on the flexible printed circuit board are situated at different distances from the substrate.

15. The touch-sensitive device as claimed in claim 14, further comprising:
a plurality of grounding wires, wherein each of the grounding wires is disposed on a boundary between the two adjacent bonding areas.

16. The touch-sensitive device as claimed in claim 14, wherein a plurality of bonding pads are disposed in each of the bonding areas.

17. The touch-sensitive device as claimed in claim 14, further comprising:
a plurality of bus lines disposed on the flexible printed circuit board, wherein the plurality of second electrodes are divided into multiple electrode groups, each electrode group is formed by the second electrodes collected from each of the blocks, and the conductive wires connected to the second electrodes in the same electrode group are all connected to the same bus line.

18. The touch-sensitive display device as claimed in claim 17, wherein the bus lines are made of metal.

19. The touch-sensitive device as claimed in claim 14, further comprising:
a decorative layer disposed on a periphery of the substrate.

20. The touch-sensitive device as claimed in claim 19, wherein the decorative layer comprises at least one of ceramic, diamond-like carbon, colored ink, photo resist and resin.

21. The touch-sensitive device as claimed in claim 14, further comprising:
a passivation layer disposed on the substrate and covering the touch-sensing electrode structure.

22. The touch-sensitive device as claimed in claim 21, wherein the passivation layer is a refractive-index matching layer.

23. The touch-sensitive device as claimed in claim 14, wherein the substrate is an encapsulation substrate of an OLED, a color filter substrate, or an array substrate.

24. A touch-sensing electrode structure, comprising:
a plurality of first electrodes, each of the electrodes having a major part extending in a first direction and a plurality of branch parts connected to the major part; and
a plurality of second electrodes, disposed on at least one side of each major part, wherein each of the second electrodes at least spreads over a region between two adjacent branch parts of each of the first electrodes, and the branch parts of one of the first electrodes have different widths measured in a second direction different to the first direction.
